(19) United States
(12) Patent Application Publication
(10) Pub. No.: US 2013/0335112 A1
(43) Pub. Date: Dec. 19, 2013

(54) DEVICE FOR TESTING ELECTRONIC COMPONENT DEVICES

(71) Applicant: Multitest elektronische Systeme GmbH, Rosenheim (DE)

(72) Inventor: Bernhard Lorenz, Marzling (DE)

(21) Appl. No.: 13/917,482

(22) Filed: Jun. 13, 2013

(30) Foreign Application Priority Data
Jun. 18, 2012 (EP) 12 172 426.4

(51) Int. Cl. G01R 1/04

(52) U.S. Cl. CPC G01R 1/0408
USPC 324/755.01

(57) ABSTRACT

A device for testing electronic component devices mounted on a substrate, having test pins which can be placed on contact surfaces of the substrate. A frame-like support structure is provided, which supports the substrate such that the individual component devices are located in open spaces of the support structure.

### CROSS REFERENCE TO RELATED APPLICATION(S)

This application claims priority to and the benefit of the filing date of European Patent Application No. 12172426.4 filed 18 Jun. 2012, the disclosure of which is hereby incorporated herein by reference.

### FIELD OF THE INVENTION

The invention relates to a device for testing of electronic component devices.

### BACKGROUND OF THE INVENTION

In order to save space on printed circuit boards, the integration density of electronic components continues to grow. To this end, in recent times different component devices have begun to be stacked vertically and three-dimensionally interconnected to form so-called 3D-ICs. The vertical connection of the individual component devices is preferably realized in TSV technology (Through-Silicon-Via). In TSV technology the connection between the individual horizontal layers is made by vertical metallic connections with a diameter of approximately 5 microns. These 3D TSV-ICs are highly integrated in relation to their base surface area and their behaviour is extremely robust.

The higher rejection rate caused by the high level of integration can be minimised by testing not only the finished ICs, but also if the stack is tested whenever a new component device is connected to the existing stack and contacted with a through-hole. In this way, many errors can be detected at a very early stage of production, and possibly even repaired.

The ICs are located on the substrate right up to production completion and are only then singularized by sawing them apart. The intermediate tests prior to the completion of the individual ICs must therefore take place on the substrate.

The contacts onto which the test pins can be placed are located on the rear of the substrate relative to the component stacks. With the test contacts numbering up to 1000 and given a required contact force of about 0.2 N per test pin, the result is a force of approximately 200 N pressing on to the very small surface area of an IC. As the substrate is very thin, high mechanical stresses are produced within the substrate that can cause damage.

### SUMMARY OF THE INVENTION

There may be a need for a device for testing electronic component devices which are mounted on a substrate, such that a plurality of test steps can be carried out on the substrate during the manufacture of the component devices without causing damage to the substrate, the component devices and/or the connection between the substrate and the component devices.

According to an embodiment of the invention, a device for testing electronic component devices having the features of claim 1 is provided. The term electronic component devices refers to all finished components, but also components during the production process onto which further layers are applied, or which are still connected to further components in a vertical stack.

According to embodiments of the invention, a frame-like support structure is provided, which supports the substrate such that the individual component devices are located in open areas of the support structure. The frame-like support structure can be formed by a closed frame, but it can also be composed of individual sections that support the parts of the substrate on which no component devices are mounted. The substrate rests on the frame-like support structure with such regions, which are later sawn in order to singularize the finished component devices.

In this way the substrate is mounted such that no direct forces act on the very sensitive component devices themselves, because both the frame-like support structure is spaced a distance apart from the side walls of the component devices, and the bottom of the supporting structure is spaced a distance apart from the surface of the component devices onto which further layers are to be applied. Hence, the pressure of the test pins can be dissipated over the frame-like structure without damaging the component devices or the substrate.

Advantageously, the frame-like support structure is arranged around a group of component devices. Thus a group can be formed, for example, by a row of component devices on the substrate. In component devices with a relatively small number of contacts, which are contacted with correspondingly fewer test pins and are loaded with a lower force, it can also be sufficient to arrange the frame-like support structure around a different group of component devices, for example an array of four component devices.

If only one row of component devices on a substrate is always examined at the same time, it may be reasonable to form the groups for the frame-like support structure from the rows of component devices arranged perpendicular thereto. As a result of this measure, the substrate above the frame-like support structure for a group of component devices is only ever simultaneously loaded with the force of the test pins for a single component device.

The number and arrangement of component devices on a substrate vary widely and depend on the nature of the component devices. If the spacing between the component devices is large on all sides, i.e. from each of the adjacent component devices, or if the pressure applied by the test pins is high, it makes sense to have the frame-like support structure arranged around each component device. This means that support is provided for the substrate on each side of every component device and the pressure of the test pins can be absorbed even better. This measure is particularly important when the component devices of the substrate are tested sequentially rather than simultaneously.

When testing several components simultaneously it may happen that in the case of the external components in particular, due to the pressure of the test pins on the contact surfaces the free edge of the substrate tilts slightly in the direction of the test pins, thereby generating a slight bending within the substrate in the area of the component device. In certain cases therefore, in spite of a frame-like support structure, damage may be caused to the substrate, the component device or the connection between the substrate and component device. It is therefore particularly advantageous that at least one clamping element is provided facing the support structure, which in its clamped position presses the substrate onto the frame-like support structure perpendicular to the plane of the substrate, and holds it in place there.

This clamping prevents the tilting of the free edge of the substrate, so that the bending or deflection of the substrate can also be reduced considerably. Just as in the case of the frame-like support structure itself, the clamping element can also have a frame-like structure, or a plurality of individual clamping elements can be used, which together also produce a frame-like support structure.

It is advantageous if the frame-like support structure or the at least one clamping element is pre-tensioned. This measure allows the clamping force to be precisely adjusted. The clamping force should be set so that a secure fixing of the substrate prevents the described stress effects, but without causing destructive forces to act on the substrate. The pre-tensioning can be produced by a spring, for example, in particular a leaf spring, or by an elastomer structural part.

According to embodiments of the invention, the at least one clamping element builds up a clamping force before the test pins are placed on the contact pads of the substrate. This can be achieved by making the distance between the at least one clamping element and the substrate less than the distance between the test pins and the contact pads of the substrate. If the frame-like supporting structure with the substrate then moves towards the test pins, the at least one clamping element rests on the substrate and clamps this with the given pre-tension between the at least one clamping element and the frame-like support structure. Only then are the test pins placed on the contact pads of the substrate. It is particularly advantageous therefore that the at least one clamping element is pre-tensioned and integrated in the test base, or at least rigidly connected thereto.

The test base with the test pins is typically connected via a loadboard to a test head. This test head is in turn connected to a computer via a plurality of conductors. The test head together with the test base is therefore fixed in position and is not movable. The frame-like support structure with the substrate resting thereon is therefore advantageously pressed against the at least one clamping element and the test pins by a compression die.

Advantageously the at least one clamping element presses the substrate onto the frame-like support structure, which is arranged around a group of component devices. This group of component devices can consist of or can comprise a series of component devices, an array of four component devices for example, or even of all component devices on the substrate.

In the case of component devices which are arranged between other component devices, such a severe deformation of the substrate cannot occur, since the force of the test pins, which press on the neighboured component devices, also presses the area surrounding this component in the direction of the supporting frame-like structure. By contrast, in the case of component devices which are arranged on the edge of a group and therefore at least on one side have either no or only distant neighbouring component devices, this force only exists at the sides with neighbouring component devices, but not on the “open” side or the “open” sides. It is therefore particularly important to clamp the substrate in the area which is arranged around a group of component devices.

If small components in particular are distributed over the substrate with a larger distance, it may be practical to clamp the substrate all around each component. Precisely when a large number of test pins is required and a high pressure force thereby acts on the substrate over a relatively small area, this measure may reduce the stress in the substrate, but also at the connection position between the substrate and the component. The at least one clamping element therefore advantageously presses the substrate onto the frame-like support structure which is arranged around each component device.

If the at least one clamping element is designed to be particularly wide at multiple positions in order to provide a maximally high clamping force, any tilting moments acting on the substrate must be prevented at all costs. A part of the at least one clamping element, which overhangs or protrudes the frame-like support structure in its width, is therefore supported by at least two parallel parts of the frame-like structure. This measure enables tilting moments to be reliably avoided.

### BRIEF DESCRIPTION OF THE DRAWINGS

Further details and advantages of embodiments of the invention are obtained from the description of an exemplary embodiment, which will be explained in detail based on the drawing.

FIG. 1 is a schematic view of a device according to an embodiment of the invention for testing electronic component devices that are mounted on a substrate;

FIGS. 2a, 2b and 2c, are plan views of different frame-like support structures for the substrate;

FIG. 3 is a plan view of a substrate with electronic component devices to be tested;

FIG. 4 is a sectional view through a part of the test base and the frame-like support structure; and

FIG. 5 is a side view of one embodiment of the frame-like support structure and the clamping elements.

### DETAILED DESCRIPTION OF THE DRAWINGS

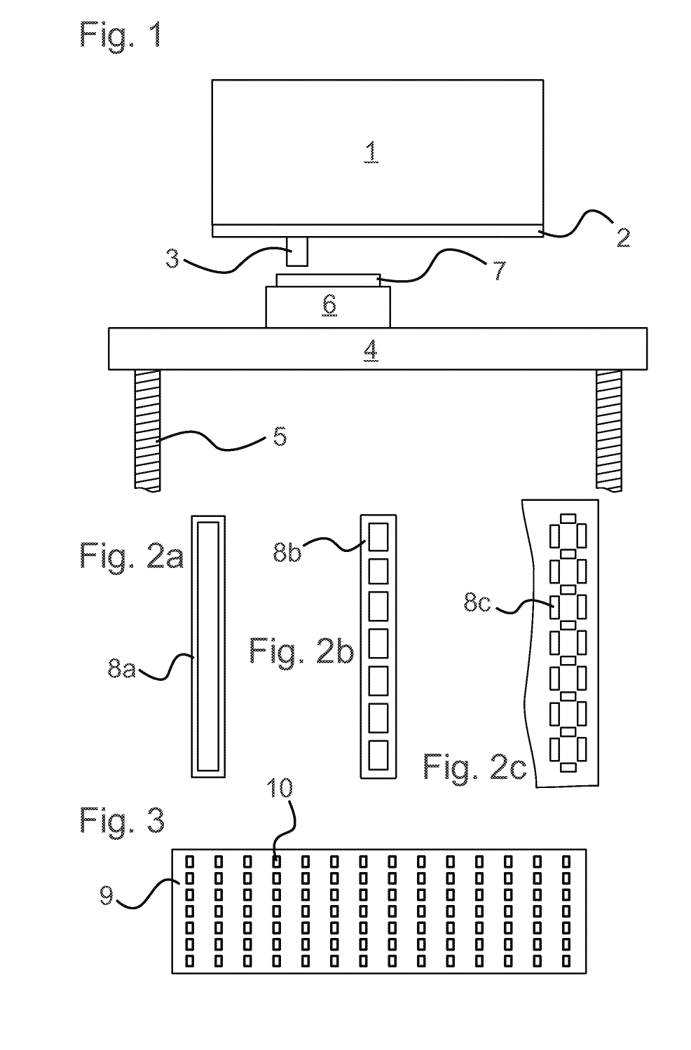

The device shown in FIG. 1 has a compression die 5, which can be moved evenly up and down by the threaded rods 8. On the compression die the retainer 6, also referred to as a nest, is provided, which contains a holder 7 for the substrate, not visible in this illustration, and, together with an X-Y displacement device not shown here, forms a positioning and holding device for the substrate 9 (see FIG. 3).

By means of the retainer 6, the substrate 9 can be positioned underneath the test base 3 with high accuracy. The component devices 10 shown in FIG. 3 are mounted on the substrate 9.

The test head 1 is mounted above the compression die 5 and the retainer 6 as a fixed, immovable module. The connection between the test head 1 and the test base 3 is provided by the loadboard 2.

To test the component devices 10 the compression die 5 is moved upwards and the contacts on the substrate 9 are pressed with a large force against the test pins of the test base 3. The component devices 10 are mounted opposite the contacts, on the underside of the substrate.

FIGS. 2a-2c show different clamping elements 8a-c, which are integrated in the test base 3. The holder 7 also has a structure, as is clearly seen from FIGS. 2a-2c. If the component devices 10 are mounted on the substrate 9 in rows, as shown in FIG. 3, then frame-like structures in accordance with the form shown in FIG. 2a are appropriate for the holder 7, for the support of the substrate.

If many test pins are needed and each component device 10 thereby has a large force applied to it, then it is better to support the substrate 9 on all sides of each individual component device 10. A corresponding shape of the frame-like support structure is shown in FIG. 2b. In a variation of the frame-like support structure according to FIG. 2b a plate is provided, which has a corresponding opening for each component device 10. The openings or holes in the support structures are dimensioned such that the bounding surfaces of the component devices 10 are not touched.

The frame-like support structure needs not necessarily form a closed structure however. The shape shown in FIG. 2c is also possible. The structure shown there can be continued to the left, so that a lattice is created in which openings all component devices 10 of the substrate 9 can be retained. But also, for each row of the component devices 10 on the substrate 9, a separate frame-like support structure can be provided, such as are shown in FIGS. 2a-c.

At least one clamping element 8a-c is integrated in the test base 3. Typically with the test base 3, a plurality of component devices 10 is always tested at the same time. The clamping element should at least be designed such that the substrate 9 is always clamped around the component devices to be simultaneously tested. For example, the clamping element 8a is provided so that a row of the component devices 10 on the substrate 9 is tested at the same time. If there is a large number of test pins, it is practical to use a clamping element which not only clamps the substrate externally around the component devices to be simultaneously tested, but which like the tensioning or clamping elements 8b and 8c, also clamps the substrate 9 between the component devices to be simultaneously tested.

Since the substrate 9 is fixed in the holder 7 during the testing of the component devices 10, the frame-like support structure shall be designed so that the substrate 9 is supported at the relevant points throughout the entire test. During the clamping on the other hand, the whole substrate shall be taken into account only if a test base is used which tests all component devices 10 at the same time. But if only one group of component devices is tested at the same time, be it a row or an array of component devices, the substrate needs also only be clamped in this area. A similar situation prevails in the context of individual testing. If all component devices 10 are tested in sequence, only the area of the substrate surrounding the component to be tested is clamped.

The shape of the clamping elements and the shape of the frame-like support structure need only be matched to one another. Thus, in the case of a lattice-shaped frame-like support structure which supports the substrate around each component, it may be practical to use a clamping element, corresponding to the clamping element shown in FIG. 2a. In particular, if one row of the component devices 10 on the substrate 9 is always to be tested with the test base 3 at the same time, this combination is appropriate.

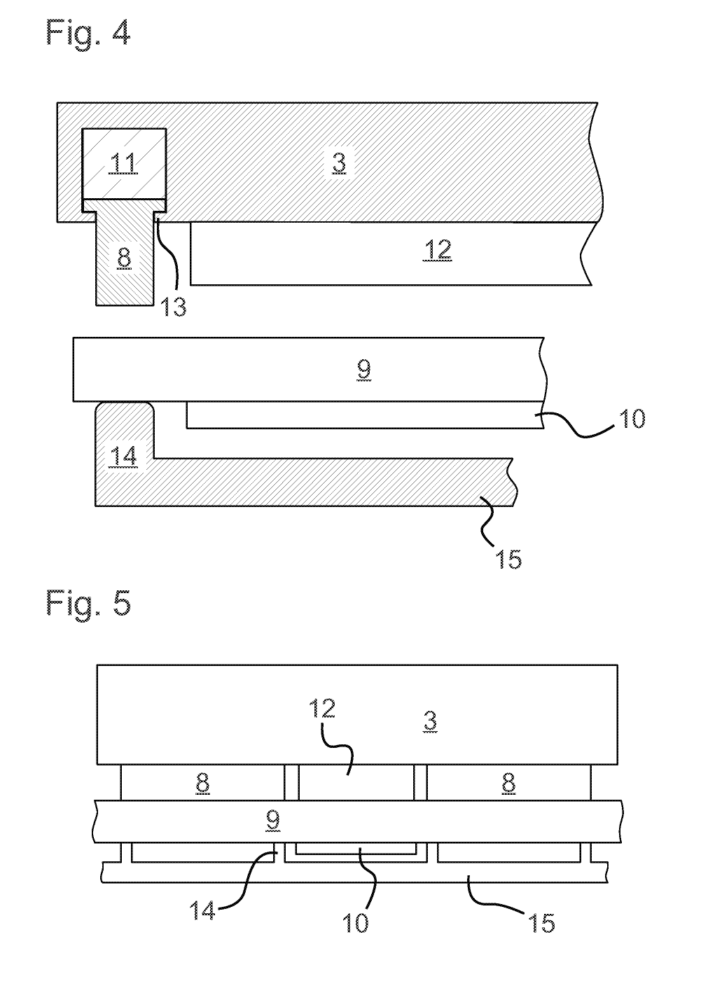

Further details of the device according to an embodiment of the invention are shown in FIG. 4. The test base 3 has a recess into which an elastomer element 11 is inserted. The elastomer element 11 holds the clamping element 8 under pre-tension, while the flange 13 prevents the clamping element 8 from being squeezed out of the recess in the test base 3 by the elastomer element 11. The test pins 12, which are only schematically illustrated here as a block, are also under pre-tension. Their distance from the substrate 9 is larger than the distance of the clamping element 8 from the substrate 9, however.

The substrate 9 rests on the support limb 14 of the frame-like supporting structure. The frame-like support structure is dimensioned such that the component device 10 is not touched anywhere on the underside of the substrate 9. The base area 15 also is also a corresponding distance away from the component device 10.

If the compression die 4 with the retainer 6 and the support 7 (see FIG. 1) is now moved upwards, the substrate 9 first contacts the clamping element 8. The clamping force, which is adjusted by the elastomer element 11, takes effect immediately and fixes the substrate 9 even before the test pins 12 come into contact with the contact pads of the substrate 9. A possible bending or deflection of the substrate 9 in the area of the test pins 12 can be thereby significantly reduced.

In FIG. 5 another possible combination is shown between the frame-like support structure and clamping element. In the exemplary embodiment illustrated the components of a row on the substrate 9 are always intended to be tested at the same time. For this purpose the test base 3 has a large number of test pins 12, which are arranged to correspond with the number of the component devices 10 to be tested. The frame-like supporting structure with its support limbs 14 and the base area 15 forms a lattice-like network in plan view.

As shown in FIG. 3, the individual rows of component devices are spaced a greater distance apart than are the component devices within a row. The width of the clamping elements 8 here is dimensioned such that they extend across two parallel support limbs 14. In this manner a high retaining force can be obtained without the possibility of tilting moments being applied to the substrate 9 by the clamping elements 8.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A device for testing electronic component devices which are mounted on a substrate, having test pins which can be placed on contact surfaces of the substrate, wherein a frame-like support structure is provided which supports the substrate such that the individual component devices are located in open spaces of the support structure.

2. The device according to claim 1, wherein the frame-like support structure is arranged around a group of component devices.

3. The device according to claim 1, wherein the frame-like support structure is arranged around each component device.

4. The device according to claim 1, wherein at least one damping element opposite the support structure is provided, which, in its damped position presses the substrate onto the frame-like support structure perpendicularly to the plane of the substrate and holds it in place there.

5. The device according to claim 1, wherein the frame-like support structure or the at least one damping element is pre-tensioned.

6. The device according to claim 1, wherein the at least one damping element builds up a damping force before the test pins come to rest on the contact surfaces of the substrate.

7. The device according to claim 1, wherein the frame-like support structure with the substrate resting thereon is pressed against the at least one damping element and the test pins by a compression die.

8. The device according to claim 1, wherein the at least one damping element presses the substrate onto the frame-like support structure, which is arranged around a group of component devices.

9. The device according to claim 1, wherein the at least one damping element presses the substrate onto the frame-like support structure, which is arranged around each component device.

10. The device according to claim 1, wherein a part of the at least one damping element, which protrudes over the frame-like support structure in width, is supported by at least two parallel parts of the frame-like support structure.
